(19) United States
(12) Patent Application Publication
(10) Pub. No.: US 2024/0312935 A1
(43) Pub. Date: Sep. 19, 2024

(54) BONDING SEMICONDUCTOR DEVICE, AND CHIP FOR BONDING SEMICONDUCTOR DEVICE AND MANUFACTURING METHOD OF THE SAME

(71) Applicant: Samsung Electronics Co., Ltd., Suwon-si (KR)

(72) Inventors: Joo Hee JANG, Suwon-si (KR); Kwangjin MOON, Suwon-si (KR); Seokho KIM, Suwon-si (KR); Soonwook KIM, Suwon-si (KR); Kunsang PARK, Suwon-si (KR)

(73) Assignee: Samsung Electronics Co., Ltd., Suwon-si (KR)

(21) Appl. No.: 18/467,199

(22) Filed: Sep. 14, 2023

(30) Foreign Application Priority Data
Mar. 15, 2023 (KR) 10-2023-0034082

(51) Int. Cl. H01L 23/00; H10B 80/00

(52) U.S. Cl. CPC H01L 24/08; H01L 24/80; H10B 80/00; H01L 2224/08145; H01L 2224/80895; H01L 2224/80896

(57) ABSTRACT

A bonding semiconductor device according to at least one embodiment is formed by bonding a first chip and a second chip, and includes a chip region and a partition region. A bonding pad formed by bonding a first bonding pad of the first chip and a second bonding pad of the second chip may be provided in the chip region. A separation pattern portion in which a first base layer of a first pattern portion of the first chip and a second base layer of a second pattern portion of the second chip are entirely separated from each other to have an inner space may be provided in the partition region.

### CROSS-REFERENCE TO RELATED APPLICATION

This application claims priority to and the benefit of Korean Patent Application No. 10-2023-0034082 filed in the Korean Intellectual Property Office on Mar. 15, 2023, the entire contents of which are incorporated herein by reference.

### BACKGROUND

The present disclosure relates to a bonding semiconductor device, and a chip for the bonding semiconductor device and a manufacturing method of the same.

In order to improve the performance, storage, and/or processing capacity of a semiconductor device, a bonding semiconductor device, in which a plurality of semiconductor chips are stacked and bonded, has been proposed. In order to improve productivity, individual bonding semiconductor devices may be manufactured by forming a bonding semiconductor device having a plurality of chip regions and then dividing the bonding semiconductor device into a plurality of bonded chips.

In a process of bonding a plurality of chips that form a bonding semiconductor device, an unbonded portion and cracks may occur depending on the properties of a bonding surface of the chips. Additionally, the unbonded portion, cracks, or the like may spread or progress to a chip region, and may cause quality deterioration or defects of an individual bonding semiconductor device. Therefore, in order to improve reliability of the bonding semiconductor device or individual semiconductor device, a structure of the bonding surface of the chip so such that a unbonded portion, cracks, or the like is not generated may be improved.

### SUMMARY

Embodiments are to provide a bonding semiconductor device that can improve reliability, and a chip for the bonding semiconductor device and a manufacturing method of the same.

A bonding semiconductor device according to an at least embodiment comprises a first chip including a first bonding pad; and a second chip including a second bonding pad, wherein the bonding semiconductor device includes a chip region and a partition region, the chip region includes a bonding pad comprising the first bonding pad of the first chip bonded to the second bonding pad of the second chip, and the partition region includes a separation pattern portion in which a first base layer of a first pattern portion of the first chip and a second base layer of a second pattern portion of the second chip are entirely separated from each other and define an inner space.

A chip for a bonding semiconductor device including a chip region and an external region, according to at least one embodiment, includes a substrate; an insulation layer on the substrate and defining a first trench portion and a second trench portion, the first trench portion in the chip region and having a first size and the second trench portion in the external region and having a second size larger than the first size; a bonding pad in the first trench portion; and a pattern portion in the second trench portion, the pattern porting including a base layer, wherein an uppermost surface of the base layer is lower than an upper surface of the insulation layer.

In a manufacturing method for a chip for a bonding semiconductor device including a chip region and an external region, according to at least on embodiment, includes forming an insulation layer on a substrate such that the insulation layer includes a first trench portion and a second trench portion, the first trench portion in the chip region and having a first size and the second trench portion in the external region and having a second size larger than the first size: forming a metal layer on the insulation layer such that the metal layer fills at least a part of the first trench portion and the second trench portion; and removing a portion of the metal layer such that a bonding pad is formed inside the first trench portion and a pattern portion, including a base layer, is formed inside the second trench portion and an uppermost surface of the base layer is lower than an upper surface of the insulation layer.

According to at least one embodiment, the pattern portion in the partition region and has a relatively large size and is formed of a separation pattern portion having an inner space or an internal space, and thus the first insulation layer and the second insulation layer in the partition region may be entirely bonded. Therefore, it is possible to prevent unbonded portions, voids, cracks, and the like from being formed in the partition region on a bonding surface of the first chip and second chip by the separation pattern portion having the inner space, as discussed in further detail below. This prevents cracks from spreading to the chip region in a subsequent heat treatment process, a division process, a reliability evaluation process, and/or the like, thereby preventing quality deterioration or defects in bonding semiconductor devices or individual bonding semiconductor devices manufactured therefrom. Accordingly, the reliability of the bonding semiconductor device can be improved.

According to at least one embodiment, a bonding semiconductor device or a chip having a bonding pad in a chip region and a separation pattern portion in a partition region having different structures may be formed by a simple process. Accordingly, a bonding semiconductor device or a chip having excellent reliability can be manufactured with a simple process.

### BRIEF DESCRIPTION OF THE DRAWINGS

FIG. 1 is a top plan view of a bonding semiconductor device according to at least one embodiment.

FIG. 2 is a cross-sectional view of the bonding semiconductor device shown in FIG. 1, taken along lines A-A′ and B-B′.

FIG. 3A to FIG. 3D illustrate one example of a manufacturing method of the bonding semiconductor device shown in FIG. 1.

FIG. 4A to FIG. 4D illustrate another example of a manufacturing method of the bonding semiconductor device shown in FIG. 1.

FIG. 5 is a partial cross-sectional view of a bonding semiconductor device according to at least one embodiment.

FIG. 6 is a partial cross-sectional view of a bonding semiconductor device according to at least one embodiment.

FIG. 7A to FIG. 7D illustrate an example of a manufacturing method of the bonding semiconductor device shown in FIG. 6.

FIG. 8 is a partial cross-sectional view of a bonding semiconductor device according to an at least one embodiment.

FIG. 9 is a partial top plan view of a bonding semiconductor device according to at least one embodiment.

FIG. 10 is a partial cross-sectional view of the bonding semiconductor device shown in FIG. 9, taken along lines C-C′ and D-D′.

FIG. 11 is a schematic cross-sectional view of an example in which a bonding semiconductor device according to at least one embodiment is formed of a bonding memory device.

### DETAILED DESCRIPTION

Hereinafter, with reference to accompanying drawings, various embodiments of the present disclosure will be described in detail and thus a person of an ordinary skill can easily practice them in the technical field to which the present disclosure belongs. The present disclosure may be embodied in many different forms and is not limited to the embodiments described herein.

In order to clearly explain the present disclosure, parts irrelevant to the description are omitted, and the same reference numerals are applied to the same and/or similar constituent elements throughout the specification.

In addition, the size and thickness of each component shown in the drawing are shown for convenience of explanation, but the present disclosure is not necessarily limited to sizes and thickness shown the drawing. More specifically, in the drawings, the thickness of layers, films, panels, regions, etc., are exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “on” a reference portion will be understood to mean disposed above or below the reference portion, and will not necessarily be understood to mean disposed “at an upper side” based on an opposite to gravity direction. Additionally, spatially relative terms, such as “lower,” “upper,” “top,” and/or the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, the device may be otherwise oriented (rotated 90 degrees or at other orientations) and the spatially relative descriptors used herein interpreted accordingly.

In addition, unless explicitly described to the contrary, the word “comprise”, and variations such as “comprises” or “comprising”, will be understood to imply the inclusion of stated elements and not the exclusion of any other elements.

Further, throughout the specification, when it is referred to as “on a plane” or “in a plane”, it means when a target portion is viewed from a top, and when it is referred to as “on a cross-section” or “in a cross-section”, it means a target portion is viewed from a side in a cross-section vertically cutting the target portion.

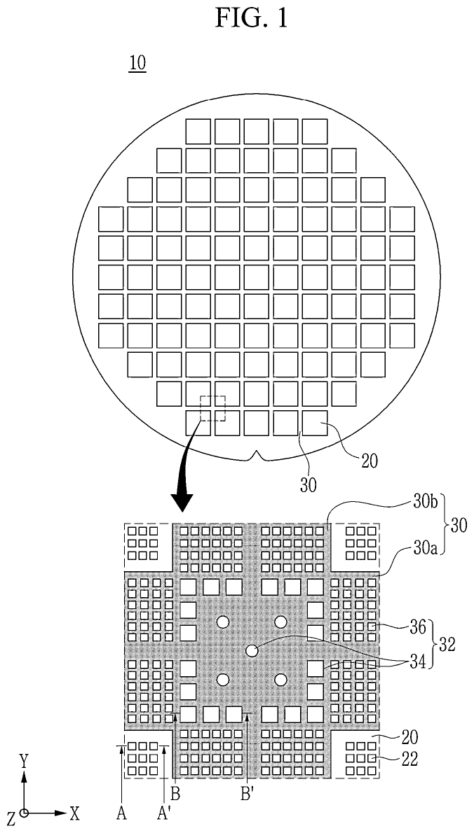

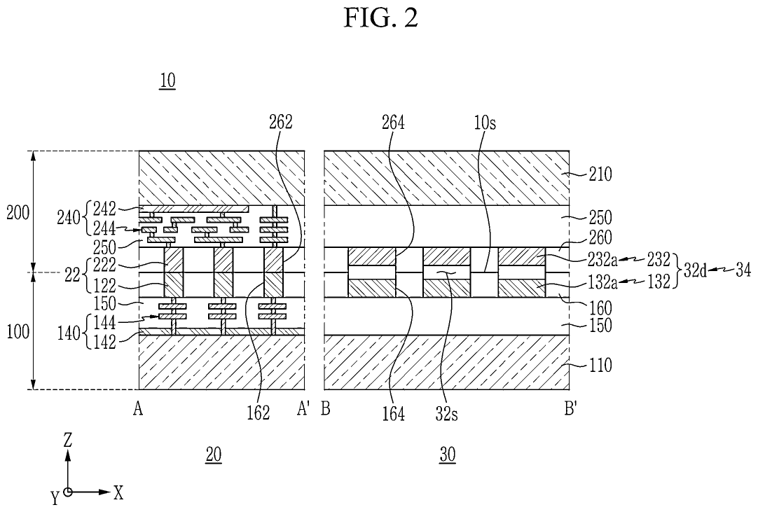

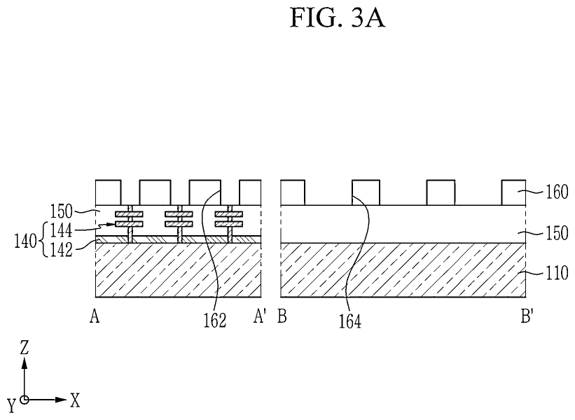

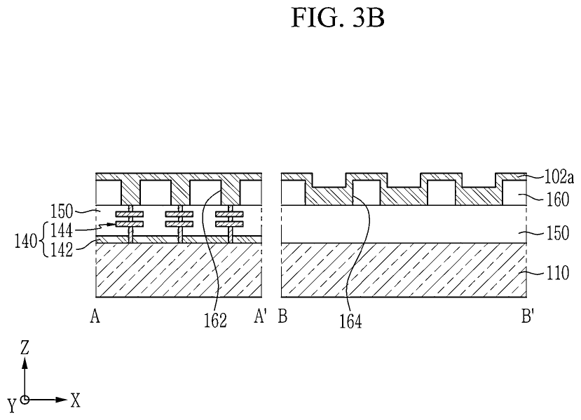

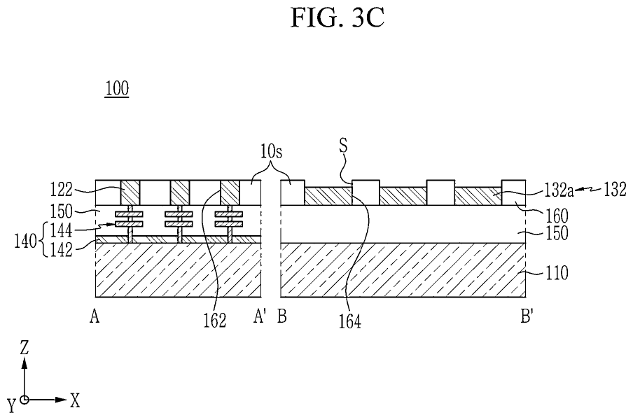

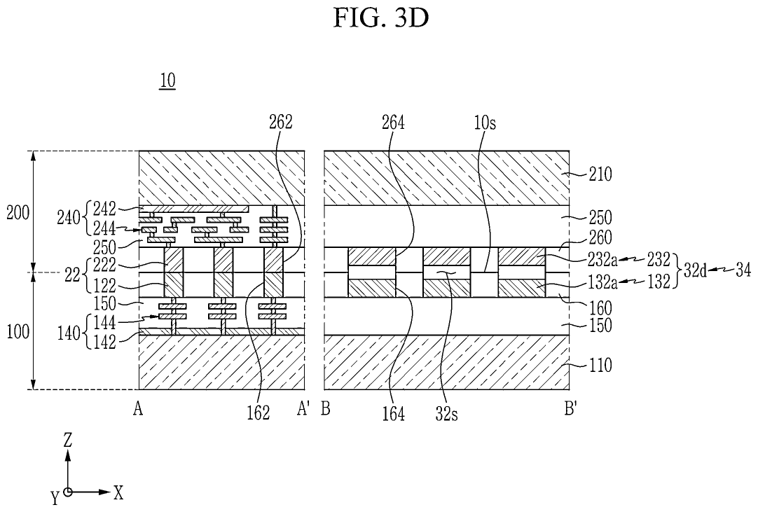

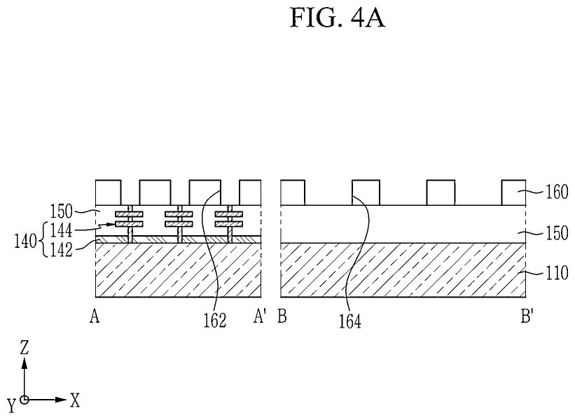

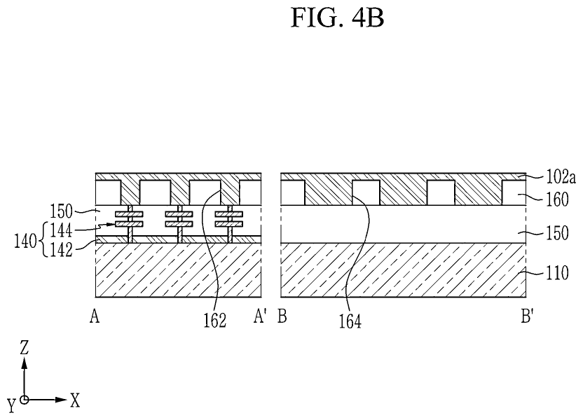

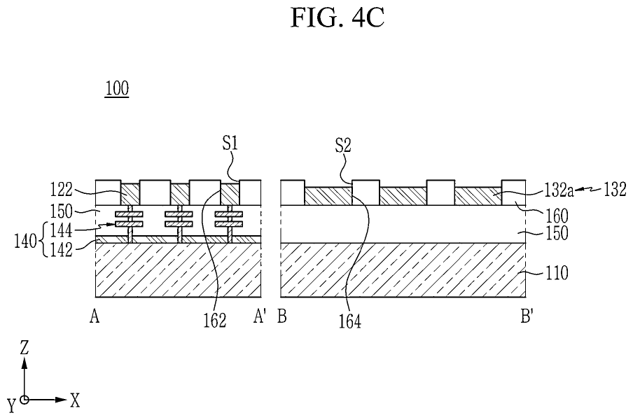

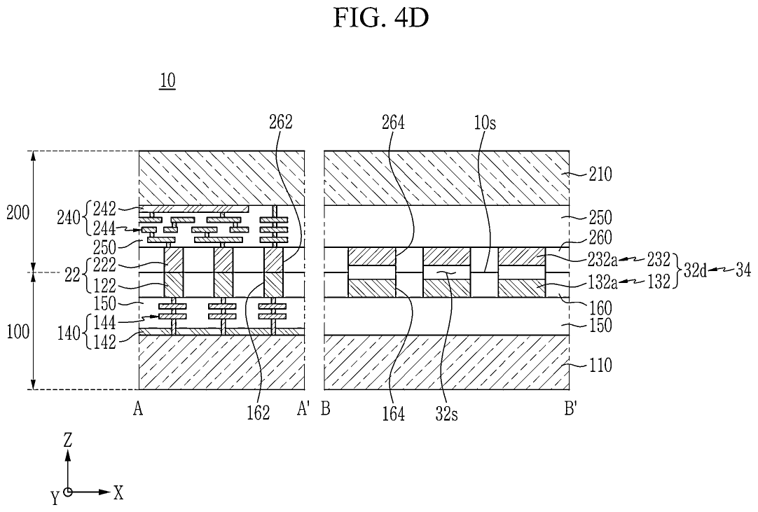

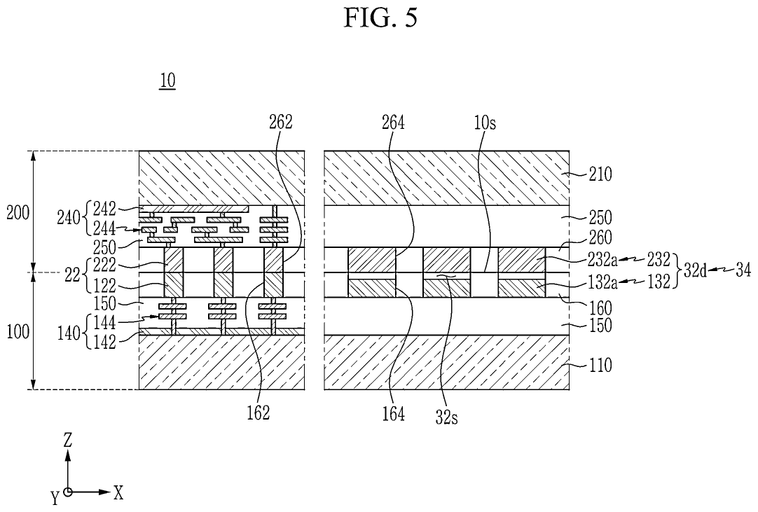

Hereinafter, a bonding semiconductor device according to at least one embodiment and a manufacturing method thereof will be described in detail with reference to FIG. 1, FIG. 2, FIG. 3A to FIG. 3D, FIG. 4A to FIG. 4D, and FIG. 5. For reference, upper and lower portions in this specification may be based on or may be defined with respect to a first or second substrate 110 or 210. That is, a portion adjacent to a first surface of the first or second substrate 110 or 210 may be defined as a lower portion and the first surface defined as a bottom surface, and, correspondingly, a portion positioned adjacent to an opposite surface of the first or second substrate 110 or 210 may be defined as an upper portion and the opposite surface defined as a top surface.

FIG. 1 is a top plan view of a bonding semiconductor device according to at least one embodiment, and FIG. 2 is a partial cross-sectional view of the bonding semiconductor device shown in FIG. 1, taken along lines A-A′ and B-B′.

Referring to FIG. 1 and FIG. 2, a bonding semiconductor device 10 according to at least one embodiment is formed by bonding a first chip 100 and a second chip 200, and includes a chip region 20 and a partition region 30. In the at least one embodiment, a bonding pad 22 is provided in the chip region 20, and a separation pattern portion 32d is provided in the partition region 30. The bonding pad 22 may be formed by bonding a first bonding pad 122 provided with the first chip 100 and a second bonding pad 222 provided with the second chip 200. In the separation pattern portion 32d, a first base layer 132a included in a first pattern portion 132 of the first chip 100 and a second base layer 232a included in a second pattern portion 232 of the second chip 200 are spaced apart from each other to define an inner space 32s. This will be described in detail.

In at least one embodiment, the bonding semiconductor device 10 may include a plurality of chip regions 20 spaced apart from each other with the partition region 30 interposed therebetween when viewed on a plane. The chip region 20 may be formed of an active region in which semiconductor device portions 140 and 240, the bonding pad 22, and the like are formed. The partition region 30 may define a predetermined (and/or otherwise determined) region including a portion to be scribed (or cut) in order for the plurality of chip region 20 to be divided into separate chip regions 20. The partition region 30 may also be referred to as a scribe lane, a scribe line, an outer region, an outside region, an external region, a cut region, and/or the like. The partition region 30 may form a boundary of the chip regions 20 by defining an edge or edges of chip region 20.

For example, a plurality of chip regions 20 form a row by positioning a plurality of chip regions 20 in a first direction (X-axis direction of the drawing), and a plurality rows of chip regions 20 may be positioned in a second direction (Y-axis direction of the drawing) crossing the first direction. In addition, the partition region 30 may include a plurality of first partition regions 30a extending long in the first direction and a plurality of second partition regions 30b extending long in the second direction. According to this, a structure of the partition regions 30 can be simplified. However, the example embodiments are not limited thereto, and the first and/or second partition regions 30a and 30b may include a curved portion, a bent portion, a rounded portion, and/or the like based on the arrangement of the plurality of chip regions 20.

The partition region 30 may include a pattern portion 32 including at least one of a key pattern 34 and a dummy pattern 36.

Here, the key pattern 34 may include patterns provided in the partition region 30 to perform a specific role. For example, the key pattern 34 may include an align mark, an overlay mark, an observation (OS) site, a test element group (TEG), and/or the like. Here, the align mark is a pattern used for aligning the first chip 100 and the second chip 200. For example, the align mark may be disposed in a region where the first partition region 30a and the second partition region 30b intersect. The overlay mark is a pattern for measuring an alignment state between a layer formed in a previous process and another layer formed in a current process. The OS site is a pattern for checking a dimension (e.g., thickness or the like) of each layer. The test element group is a pattern for testing a manufacturing process of a semiconductor device and a property of a manufactured semiconductor device. However, the embodiments are not limited to the listed types for the key pattern 34 and, other roles and/or patterns may be further provided.

The dummy pattern 36 is a pattern provided in the partition region 30 such that the partition region 30 has a property similar to that of the chip region 20 equipped with the bonding pad 22. For example, the dummy pattern 36 is configured to mitigate and/or prevent problems that may occur due to differences in properties between the chip region 20 and the partition region 30 during a manufacturing process.

For example, a chemical mechanical polishing process is highly dependent on a size, a material, etc. of a pattern being polished. Thus, when there is a difference in a size, a material, etc. of the pattern, defects (such as unwanted erosion, dishing, and/or the like) may occur. Therefore, the dummy pattern 36 is formed in the partition region 30 such that the partition region 30 and the chip region 20 have similar properties. For example, the same or similar material is exposed in the chip region 20 and the partition region 30 (and/or by the bonding pad 22 and the dummy pattern 36) to prevent a step from being formed between the chip region 20 and the partition region 30 during the chemical mechanical polishing (CMP) process.

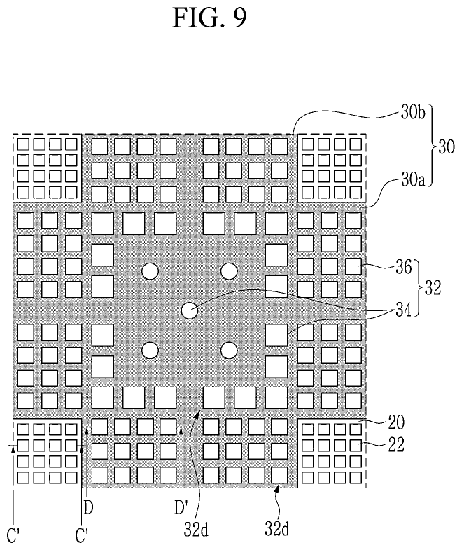

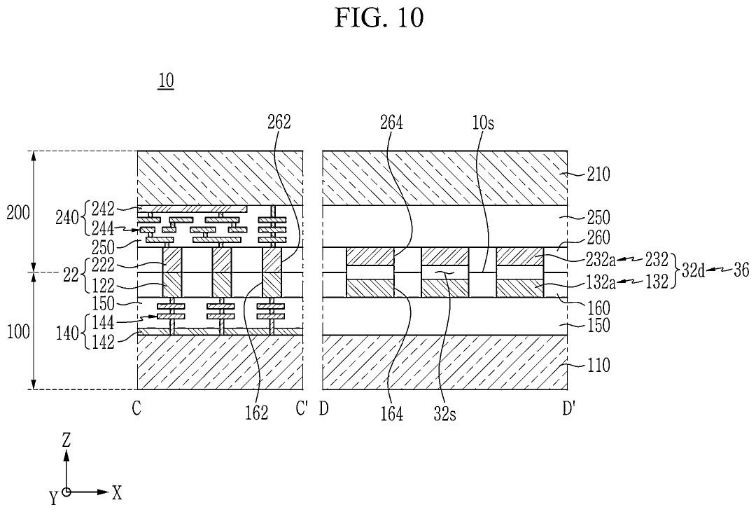

For example, the dummy pattern 36 may be formed of the same or similar material as the bonding pad 22 positioned within the chip region 20, and/or may have the same or similar size and/or pattern. Therefore, the properties corresponding to, e.g., the CMP process, of the chip region 20 and the partition region 30 may be formed to be as similar as possible. However, the embodiments are not limited thereto and other examples will be described later in detail with reference to FIG. 9 and FIG. 10.

In the drawing, the key pattern 34 is disposed in an intersection region of the first partition region 30a and the second partition region 30b, and the dummy pattern 34 is disposed in a portion other than the intersection region, but the embodiments are not limited thereto. For example, at least a part of key pattern 34 may be disposed in the partition region 30 at a portion other than the intersection region. In this way, positions of the key pattern 34 and the dummy pattern 36 may be variously modified. In addition, patterns other than the key pattern 34 and the dummy pattern 36 may be provided in the partition region 30.

In at least one embodiment, at least one of a plurality of pattern portions 32 provided in the partition region 30 may include a separation pattern portion 32d having an inner space 32s. In FIG. 2, an example is illustrated wherein at least one of the key patterns 34 is formed of a separation pattern portion 32d. This is described in more detail below.

In at least one embodiment, the bonding semiconductor device 10 may be (and/or include) a semiconductor device, a semiconductor element, a semiconductor unit, or a semiconductor package formed by bonding the first chip 100 and the second chip 200 in a thickness direction. For example, the bonding semiconductor device 10 may be a memory semiconductor device, a logic semiconductor device, an image sensor, or the like. For example, the bonding semiconductor device 10 may be (and/or include) a flash memory, a dynamic random access memory (DRAM), an static random access memory (SRAM), an electrically erasable read-only memory (EEPROM), a phase-change random access memory (PRAM), a magnetoresistive random access memory (MRAM), a high bandwidth memory (HBM), a microcomputer processor, and/or the like. However, the embodiments are not limited thereto, and the bonding semiconductor device 10 may be formed of (and/or include) various other semiconductor devices, semiconductor elements, semiconductor units, or semiconductor packages.

Here, each of the first chip 100 and the second chip 200 may be and/or include a semiconductor substrate, a semiconductor chip, a semiconductor device, a semiconductor element, a semiconductor unit, a semiconductor device, and/or the like. For example, the first chip 100 and/or the second chip 200 may include a substrate 110 and/or 210, a semiconductor device portion 140 and/or 240, first and/or second bonding pads 122 and/or 222 provided, respectively, on the substrate 110 and 210, first and/or second pattern portions 132 and/or 232, or etc.

In at least one embodiment, the bonding semiconductor device 10 may be formed by bonding the first chip 100 and the second chip 200 by hybrid bonding. Hereinafter, example structures of the first chip 100 and the second chip 200 included in the bonding semiconductor device 10 will be described respectively, and then the hybrid bonding will be described.

In at least one embodiment, the first chip 100 includes a first substrate 110, a first semiconductor device portion 140 disposed on the first substrate 110 in the chip region 20, a first bonding pad 122 disposed in the chip region 20 and electrically connected to the first semiconductor device portion 140, and a first pattern portion 132 disposed in the partition region 30. A first insulation layer 160 including a first trench portion 162 in which the first bonding pad 122 is disposed and a second trench portion 164 in which the first pattern portion 132 is disposed is provided on the first substrate 110.

In at least one embodiment, the first substrate 110 is a substrate including a semiconductor material. For example, the first substrate 110 may be a semiconductor substrate formed of a semiconductor material and/or a semiconductor substrate having a substrate and a semiconductor material layer formed on the substrate. The semiconductor material may be an elemental and/or a compound semiconductor. For example, the first substrate 110 may include single-crystalline or poly-crystalline silicon, single-crystalline or poly-crystalline germanium, single-crystalline or poly-crystalline silicon-germanium, silicon-on-insulator, germanium-on-insulator, etc. However, the embodiments are not limited thereto, and the first substrate 110 may be or include other materials.

The first semiconductor device portion 140 is disposed on the first substrate 110 in the chip region 20. The first semiconductor device portion 140 may include a first semiconductor device layer 142 and a first wiring portion 144. The first semiconductor device layer 142 may include elements, structures, circuits, and/or the like selected based on the role and/or function of the first chip 100. For example, the first semiconductor device layer 142 may include processing circuitry and/or memory, and therefore may include a wiring pattern, a transistor, a capacitor (CAP), a resistor (R)-inductor (L)-capacitor (C) circuit (RLC circuit), and/or the like (not illustrated). The first wiring portion 144 may electrically connect the first semiconductor device layer 142 and the first bonding pad 122. The first wiring portion 144 may include one wiring layer or a plurality of wiring layers stacked with a first intermediate insulation layer 150 therebetween and connected through a contact plug, a contact via, and/or the like.

The wiring layers and/or the contact plugs of the first wiring portion 144 may include a conductive material and may be formed as a single layer or a plurality of layers. For example, the wiring layer and/or the contact plug of the first wiring portion 144 may include a metal, such as at least one of copper, aluminum, tungsten, nickel, gold, tin, manganese, cobalt, titanium, and/or an alloy including the same. However, the embodiments are not limited thereto, and the first wiring portion 144 may include other and/or additional materials.

In the partition region 30, the first intermediate insulation layer 150 may be provided on the first substrate 110 without the first semiconductor device portion 140. To provide concise illustrations and a clear understanding, FIG. 2 illustrates that the first intermediate insulation layer 150 disposed in the partition region 30 and the first intermediate insulation layer 150 disposed in the chip region 20 are formed of the same layer, but the embodiments are not limited thereto.

In the chip region 20 and the partition region 30, a first insulation layer 160 may be disposed on the first semiconductor device portion 140 and/or the first intermediate insulation layer 150. The first insulation layer 160 may include first and second trench portions 162 and 164 where a first bonding pad 122 and a first pattern portion 132 are provided, respectively. For example, the first insulation layer 160 may be disposed to, except for the first and second trench portions 162 and 164, entirely cover an upper surface of the chip region 20 and the partition region 30.

The first intermediate insulation layer 150 and/or the first insulation layer 160 may include various insulating materials and may be formed of a single layer or a plurality of layers. For example, the first insulation layer 160 may include at least one of a silicon oxide, a silicon nitride, a silicon carbonitride (SiCN), and/or the like. For example, the silicon carbonitride may be provided at a bonding surface 10s of the first insulation layer 160, but the embodiments are not limited thereto.

In the chip region 20, the first bonding pad 122 may be at the bonding surface 10s of the first chip 100. The first bonding pad 122 is disposed in the first trench portion 162 of the first insulation layer 160, and at least one surface of the first bonding pad 122 may be exposed at or through the bonding surface 10s of the first chip 100. For example, the bonding surface 10s may be an upper surface of the first insulation layer 160 and an upper surface of the first bonding pad 122, adjacent thereto, may be disposed on the same plane.

A first pattern portion 132 forming the separation pattern portion 32d adjacent to the bonding surface 10s may be provided at a side of the bonding surface 10s in the partition region 30 of the first chip 100. At least a part of one surface of the first pattern portion 132 disposed at the side of the bonding surface 10s may be spaced apart from the bonding surface 10s. This will be described in more detail below. The first pattern portion 132 may, otherwise, have the same material and/or the same structure as the first bonding pad 122. In this case, in the partition region 30, a portion forming a pattern portion other than the first pattern portion 132 forming the separation pattern portion 32d may have a material or structure suitable for its role, and may have a material or structure identical to or different from that of the first bonding pad 122.

To provide concise illustrations and a clear understanding, FIG. 2 illustrates that the bottom surfaces of the first insulation layer 160, the first bonding pad 122, and the first pattern portion 132 (opposite to the bonding surface 10s) are disposed on the same plane, but the embodiments are not limited thereto.

The second chip 200 includes a second substrate 210, a second semiconductor device portion 240 disposed on the second substrate 210 in the chip region 20, a second bonding pad 222 disposed in the chip region 20 and electrically connected to the second semiconductor device portion 240, a second pattern portion 232 disposed in the partition region 30, and a second insulation layer 260 including a first trench portion 262 in which the second bonding pad 222 is disposed and a second trench portion 264 in which the second pattern portion 232.

In at least one embodiment, the second substrate 210 is a substrate including a semiconductor material. For example, the second substrate 210 may be a semiconductor substrate formed of a semiconductor material and/or may be a semiconductor substrate having a substrate and a semiconductor material layer formed on the substrate. The semiconductor material may be an elemental and/or a compound semiconductor. For example, the second substrate 210 may include single-crystalline or poly-crystalline silicon, single-crystalline or poly-crystalline germanium, single-crystalline or poly-crystalline silicon-germanium, silicon-on-insulator, germanium-on-insulator, etc. However, the embodiments are not limited thereto, and the second substrate 210 may be or include other materials.

The second semiconductor device portion 240 is disposed on the second substrate 210 in the chip region 20. The second semiconductor device portion 240 may include a second semiconductor device layer 242 and a second wiring portion 244. The second semiconductor device layer 242 may include elements, structures, circuits, and/or the like selected based on the role and/or function of the second chip 200. For example, the second semiconductor device layer 242 may include processing circuitry and/or memory, and therefore may include a wiring pattern, a transistor, a capacitor (CAP), a resistor (R)-inductor (L)-capacitor (C) circuit (RLC circuit), and/or the like (not illustrated). The second wiring portion 244 may electrically connect the second semiconductor device layer 242 and the second bonding pad 222. The second wiring portion 244 may include one wiring layer or a plurality of wiring layers stacked with a second intermediate insulation layer 250 therebetween and connected through a contact plug, a contact via, or the like.

Descriptions of the first semiconductor device layer 142 and the first wiring portion 144 may be applied to the second semiconductor device layer 242 and the second wiring portion 244. However, in at least one embodiment, at least one of a structure, material, and an arrangement of the second semiconductor device layer 242 and the second wiring portion 244 may be different from that of the first semiconductor device layer 142 and first wiring portion 144. For example, the second chip 200 may have the same and/or a different role and/or function from the first chip 100. For example, in at least one embodiment, one of the first or second chips 100 or 200 may be configured as memory and the other may be configured as a memory controller.

In the partition region 30, the second intermediate insulation layer 250 may be provided on the second substrate 210 without the second semiconductor device portion 240. To provide concise illustrations and a clear understanding, FIG. 2 shows that the second intermediate insulation layer 250 disposed in the partition region 30 and the second intermediate insulation layer 250 disposed in the chip region 20 are formed of the same layer, but the embodiments are not limited thereto.

In the chip region 20 and the partition region 30, the second insulation layer 260 may be disposed on the second semiconductor device portion 240 and/or the second intermediate insulation layer 250. The second insulation layer 260 may include first and second trench portions 262 and 264 where a second bonding pad 222 and a second pattern portion 232 are provided, respectively. For example, the second insulation layer 260 may be disposed to, except for the first and second trench portions 262 and 264, entirely cover a surface of the chip region 20 and the partition region 30.

The description regarding a material of the first intermediate insulation layer 150 and first insulation layer 160 may also be applied to a material of the second intermediate insulation layer 250 and the second insulation layer 260. For example, the second intermediate insulation layer 250 may be formed of the same material as the first intermediate insulation layer 150 and/or a different material from the first intermediate insulation layer 150. The second insulation layer 260 may be formed of the same material as the first insulation layer 160 and/or a different material from the first insulation layer 160.

In the chip region 20, the second bonding pad 222 may be disposed at the bonding surface 10s of the second chip 200. The second bonding pad 222 is disposed on the first trench portion 262 of the second insulation layer 260, and at least one side of the second bonding pad 222 may be exposed at or through the bonding surface 10s of the second chip 200. For example, the bonding surface 10s may be a bottom surface of the second insulation layer 260 and a bottom surface of the second bonding pad 222, adjacent thereto, may be disposed on the same plane.

A second pattern portion 232 forming the separation pattern portion 32d adjacent to the bonding surface 10s may be provided at a side of the bonding surface 10s of the second chip 200 in the partition region 30. At least a part of one surface of the second pattern portion 232 disposed at the side of the bonding surface 10s may be disposed apart from the bonding surface 10s. This will be described in more detail below. The second pattern portion 232 may, otherwise, have the same material or same stacking structure as the second bonding pad 222. In this case, in the partition region 30, a portion forming a pattern portion other than the second pattern portion 232 forming the separation pattern portion 32d may have a material or structure suitable for its role, and may have a material that is the same as or different from that of the second bonding pad 222.

The bonding semiconductor device 10 may be formed by bonding the first chip 100 and the second chip 200 by a hybrid bonding process while the bonding surface 10s of the first chip 100 (e.g., a surface where the first insulation layer 160 and first bonding pad 122 are disposed) and the bonding surface 10s of the second chip 200 (e.g., a surface where the second insulation layer 260 and second bonding pad 222 are disposed) face each other. During the hybrid bonding, solder bumps and/or solder balls are not used, and thus bonding defects (e.g., due to the solder bumps or solder balls) can be prevented and a thickness of the bonding semiconductor device 10 can be reduced.

To provide concise illustration and a clear understanding, FIG. 2 illustrates that a bottom surface (an upper surface in FIG. 2) of the second insulation layer 260, a bottom surface (an upper surface in FIG. 2) of the second bonding pad 222, and a bottom surface (an upper surface in FIG. 2) of the second pattern portion 232 are disposed on the same plane, but the embodiments are not limited thereto.

Due to such hybrid bonding, the first bonding pad 122 and the second bonding pad 222 are directly contacted and bonded to form the bonding pad 22. In at least one embodiment, the first bonding pad 122 and the second bonding pad 222 may include the same metal as each other. For example, the first bonding pad 122 and the second bonding pad 222 may both include copper to be bonded using, e.g., copper-to-copper hybrid bonding structure. The bonding pad 22 may be bonded by mutual diffusion of a metal (e.g., copper) forming the first bonding pad 122 and the second bonding pad 222 in an annealing process. However, the embodiments are not limited to the above material for the first bonding pad 122 and the second bonding pad 222. For example, in another example, the first bonding pad 122 and/or the second bonding pad 222 may include at least one of aluminum, tungsten, nickel, gold, tin, manganese, cobalt, titanium tantalum, and/or an alloy including the same. In at least one embodiment, the first bonding pad 122 and/or the second bonding pad 222 may include the metal or alloy described above, along with copper. Alternatively, a composite layer of a metal oxide and a metal layer may be included. In addition, the first bonding pad 122 and the second bonding pad 222 may include different materials.

In addition, by hybrid bonding, the first insulation layer 160 and the second insulation layer 260 may be directly contacted and bonded. For example, the first insulation layer 160 and the second insulation layer 260 may directly contact each other and bond to form a dielectric-dielectric bonding structure. In at least one embodiment, the first insulation layer 160 and the second insulation layer 260 may include the same insulating material as each other. For example, in at least one embodiment, the first insulation layer 160 and the second insulation layer 260 may include a silicon carbonitride in, at least, a portion adjacent to the bonding surface 10s. The first insulation layer 160 and the second insulation layer 260 may have been bonded, e.g., by covalent bonding of materials or elements included in the first insulation layer 160 and the second insulation layer 260 in the annealing process.

In at least one embodiment, in the separation pattern portion 32d disposed in the partition region 30, the first base layer 132a of the first pattern portion 132 and the second base layer 232a of the second pattern portion 232 are completely (e.g., entirely) separated from each other such that the inner space 32s can be positioned between the first pattern portion 132 and the second pattern portion 232. Here, the first base layer 132a or the second base layer 232a may mean a layer included with the largest volume in the first pattern portion 132 or the second pattern portion 232 (e.g., a layer included to exceed 50 vol % of the first pattern portion 132 or the second pattern portion 232). For example, the first base layer 132a or the second base layer 232a may include the same (or substantially similar) material (e.g., copper) as the base layer of the first bonding pad 122 or the second bonding pad 222. Here, the base layer of the first bonding pad 122 or the second bonding pad 222 may mean a layer included with the largest volume in the first bonding pad 122 or the second bonding pad 222.

For example, the first base layer 132a may not be disposed at an upper side surface adjacent to the bonding surface 10s in the second trench portion 164 of the first insulation layer 160, and the second base layer 232a may not be disposed at an upper side surface adjacent to the bonding surface 10s in the second trench portion 264 of the second insulation layer 260. Here, upper portions of the second trench portions 164 and 264 may mean portions adjacent to the bonding surface 10s. Accordingly, surfaces of the first and second base layers 132a and 232a facing each other may be entirely spaced apart from each other with the inner space 32s interposed therebetween. For example, the first base layer 132a and the second base layer 232a may be completely or entirely spaced apart from each other with the inner space 32s interposed therebetween. As a result, the first base layer 132a and the second base layer 232a, which may otherwise cause a change in surface property or topology in the chemical mechanical polishing process, do not contact each other. Accordingly, a change in the surface property or the topology that may occur in the chemical mechanical polishing process can be prevented and/or minimized.

In at least one embodiment, the first pattern portion 132 may be formed of the first base layer 132a without other layers, and the second pattern portion 232 may be formed of the second base layer 232a without other layers. In this case, the first pattern portion 132 and the second pattern portion 232 may have a disconnection structure in which they are completely or entirely spaced apart from each other with the inner space 32s interposed therebetween. That is, the first pattern portion 132 and the second pattern portion 232, or the first base layer 132a and the second base layer 232a, which form the separation pattern portion 32d, may have a disconnection structure that does not include a metal connection structure in a cross-section.

In at least one embodiment, a dimension of the separation pattern portion 32d may be greater than a corresponding dimension of the bonding pad 22. For example, a width of the separation pattern portion 32d in one direction may be 2 times or more (e.g., 5 times or more) and 20 times or less of a width of the bonding pad 22. However, the embodiments are not limited to the size of the separation pattern portion 32d, the size of the bonding pad 22, or the like.

For reference, a chemical mechanical polishing process may be performed to improve surface roughness prior to the bonding process. In this case, when a bonding pad (e.g., first or second bonding pad) and a larger pattern portion (e.g., first or second pattern portion) are provided together, there is a difference in a degree of polishing between the bonding pad and the pattern portion in the chemical mechanical polishing process. For example, a pattern portion having a relatively larger size may protrude farther from the bonding pad after the chemical mechanical polishing process. When the bonding process is performed in such a state, unbonded portions, voids, cracks, and/or the like may occur between the first insulation layer and the second insulation layer as a result of the protruded pattern portion. These problems may occur more significantly when alkaline slurry materials are used in the chemical mechanical polishing process. Further, even in cases wherein the pattern portion does not protrude from the bonding surface of the first or second chip before the bonding process, the pattern portion having a relatively large size may expand or extrude more than the bonding pad (e.g., during the bonding process or annealing process) such that the pattern portion can be protruded. Then, unbonded portions, voids, cracks, and/or the like may occur around the pattern portion where the first insulation layer and the second insulation layer are not bonded.

Considering this, the pattern portion 32 having a relatively large size may be formed to constitute the separation pattern portion 32d. That is the first pattern portion 132 and/or the second pattern portion 232 are configured such that, before, during, and/or after the bonding process, an upper surface of the first pattern portion 132 or the second pattern portion 232 does not protrude than an upper surface of the bonding surface 10s, the first bonding pad 122, and/or the second bonding pad 222. Therefore, since the upper surface of the first pattern portion 132 or the second pattern portion 232 does not protrude than the upper surface of the bonding surface 10s or the first bonding pad 122 or the second bonding pad 222, the unbonded portions, voids, cracks, or the like resulting from such protrusions may not occur between the first insulation layer 160 and the second insulation layer 260 after the bonding process.

For example, when viewed in cross-section, the upper surface of the first base layer 132a may be disposed to be entirely lower than the upper surface of the first insulation layer 160, the bonding surface 10s, or the first bonding pad 122; and/or the lower surface of the second 232a may be disposed to be entirely higher than the lower surface of the second insulation layer 260, the bonding surface 10s, and/or the second bonding pad 222. For example, before the bonding process, wherein the second chip 200 is flipped and bonded to the first chip 100, the upper surface of the first or second pattern portion 132 or 232 may be disposed lower than the bonding surface 10s or the upper surface of the first or second bonding pad 122 or 222 by adjusting a thickness or a height of the first or second pattern portion 132 or 232. That is, in consideration of expansion or extrusion of the first or second pattern portion 132 or 232 that may occur during the bonding process and/or the annealing process, the upper surface of the first or second pattern portion 132 or 232 may be positioned lower than the upper surface of the first or second bonding pad 122 or 222 or the bonding surface 10s before the bonding process. For reference, before the bonding process, the upper surface of the first or second bonding pad 122 or 222 may be positioned on the same plane as or lower than the upper surface of the first or second insulation layer 160 or 260 or the bonding surface 10s.

In at least one embodiment, a thickness of the inner space 32s may be smaller than a sum of a thicknesses of the first pattern portion 132 and a second pattern portion 232 in the thickness direction (Z-axis direction of the drawing) of the bonding semiconductor device 10. For example, in the thickness direction of the bonding semiconductor device 10, the thickness of the inner space 32s may be smaller than a sum of a thickness of the first base layer 132a and a thickness of the second base layer 232a; a distance between the bonding surface 10s and the upper surface of the first base layer 132a may be smaller than a thickness of the first base layer 132a; and/or a distance between the bonding surface 10s and the lower surface of the second base layer 232a may be smaller than a thickness of the second base layer 232a. In at least one embodiment, a width of the separation pattern portion 32d in the first direction (the X-axis direction of the drawing) and/or the second direction (the Y-axis direction of the drawing) may be greater than the thickness of the inner space 32s. Here, the thickness of the inner space 32s may mean a minimum thickness, and the width of the separation pattern portion 32d may mean a minimum width.

As such, the separation pattern portion 32d may have excellent structural stability when the thickness of the inner space 32s has a relatively small size. That is, when the first pattern portion 132 and/or the second pattern portion 232 may be provided with a sufficient volume inside the second trench portions 164 and/or 264 of the first and/or second insulation layers 160 and 260, the second trench portions 164 and 264 and/or the first and second pattern portions 132 and 232 may be stably maintained without collapsing during the chemical mechanical polishing process. In contrast, when the first pattern portion 132 and/or the second pattern portion 232 are not provided in the second trench portions 164 and/or 264 of the first insulation layer 160 and/or the second insulation layer 260, the second trench portions 164 and 264 are not maintained and thus may collapse in the chemical mechanical polishing process. In at least one embodiment, the first pattern portion 132 and/or the second pattern portion 232 is provided to have sufficient volume inside the second trench portions 164 and/or 264 to further improve structural stability.

Accordingly, in the chip region 20, at the bonding surfaces 10s of the first chip 100 and the second chip 200, the first insulation layer 160 and the second insulation layer 260 are bonded as a whole, and the first bonding pad 122 and the second bonding pad 222 are bonded to form the bonding pad 22. Here, the bonding pad 22 may be entirely filled with a metal without an inner space to form a contacted metal connection structure. Accordingly, in the chip region 20, a metal connection structure in the bonding pad 22 and an insulation connection structure in the first insulation layer 160 and the second insulation layer 260 are provided.

Meanwhile, in the partition region 30, at the bonding surfaces 10s of the first chip 100 and the second chip 200, the first insulation layer 160 and the second insulation layer 260 are bonded as a whole, but the first base layer 132a and the second base layer 232a are spaced apart from each other to have an inner space 32s therebetween in the separation pattern portion 32d. That is, the bonding surfaces of the first insulation layer 160 and the second insulation layer 260 and the inner space 32s disposed between the first base layer 132a and the second base layer 232a may be disposed at the bonding surfaces 10s in the partition region 30. Accordingly, although the partition region 30 has an insulation connection structure of the first insulation layer 160 and the second insulation layer 260, the metal connection structure is not provided in the separation pattern portion 32d.

That is, the bonding pad 22 and the separation pattern portion 32d may have share a metal (e.g., copper), but may have different shapes or structures.

In at least one embodiment, a pattern portion (e.g., at least one of the key patterns 34) positioned in the partition region 30 and having a relatively large size is formed of the separation pattern portion 32d having the inner space 32s, while the first insulation layer 160 and the second insulation layer 260 may be entirely bonded in the partition region 30. Accordingly, unbounded portions, voids, cracks, and/or the like can be prevented from spread or progress to the chip region 20 in a subsequent heat treatment process, division process, reliability evaluation process, etc., thereby preventing and/or mitigating quality deterioration and/or defects of the bonding semiconductor device 10 (and/or the individual bonding semiconductor devices manufactured therefrom). Accordingly, reliability of the bonding semiconductor device 10 may be improved.

On the other hand, in a comparative example, wherein a first pattern portion and a second pattern portion disposed in a partitioned region and forming a pattern portion having a relatively large size are bonded in direct contact without any inner space, unbonded portions where a first insulation layer and a second insulation layer are not bonded, voids, cracks, and/or the like may be formed at a periphery of the pattern portion even after performing the bonding process.

The unbonded portions, voids, cracks, or the like may spread or progress to the chip region in the subsequent heat treatment process, division process, reliability evaluation process, or the like, and thus quality deterioration or defects of the comparative bonding semiconductor device (or individual bonding semiconductor devices manufactured therefrom) may be caused.

The bonding semiconductor device 10 according to at least one embodiment may be divided along the partition region 30 and separated into individual bonding semiconductor devices. That is, the plurality of individual bonding semiconductor devices may be formed in the plurality of chip regions 20 and then divided through the partition region 30 to manufacture the plurality of individual bonding semiconductor devices. According to this, productivity can be improved. Since at least a part of the separation pattern portion 32d may remain in each of the individual bonding semiconductor devices, each of the individual bonding semiconductor devices may include a separation pattern portion 32d.

A manufacturing method of forming the bonding semiconductor device 10 according to an example will now be described in detail below. Hereinafter, detailed descriptions regarding portions identical or extremely similar to those already described may be omitted.

A manufacturing method of the bonding semiconductor device 10 may include a process of manufacturing the first chip 100, a process of manufacturing the second chip 200, and a process of bonding the first chip 100 and the second chip 200. Hereinafter, a process of manufacturing the first chip 100 and a process of bonding the first chip 100 and the second chip 200 will be described in detail. Since a process of manufacturing the second chip 200 may be the same or substantially similar to a process of manufacturing the first chip 100, a description of the process of manufacturing the first chip 100 may also be applied to the process of manufacturing the second chip 200, and therefore a separate description of the process of manufacturing the second chip 200 is omitted.

First, referring to FIG. 3A to FIG. 3D, together with FIG. 1 and FIG. 2, an example of a manufacturing method of a bonding semiconductor device 10 will be described. FIG. 3A to FIG. 3D illustrate an example of the manufacturing method of the bonding semiconductor device 10 shown in FIG. 1. FIG. 3A to FIG. 3D illustrate portions corresponding to the lines A-A′ and the line B-B′ of FIG. 1.

As shown in FIG. 3A, a first semiconductor device portion 140, a first intermediate insulation layer 150, and a first insulation layer 160 including first and second trench portions 162 and 164 may be formed on a first substrate 110. In this case, a dimension of the second trench portion 164 (e.g., a width) in which the first pattern portion 132 is to be formed may be greater than a corresponding dimension of the first trench portion 162 in which the first bonding pad 122 is to be formed.

Since any of various processes may be applied to the forming of the first semiconductor device portion 140, the first intermediate insulation layer 150, and the first insulation layer 160 including the first and second trench portions 162 and 164, detailed descriptions thereof may be omitted.

Subsequently, as shown in FIG. 3B, a metal layer 102a may be formed on the first insulation layer 160 while filling at least a part of the first and second trench portions 162 and 164. The metal layer 102a may be formed by an additive deposition method such as electroplating and/or the like.

In this case, by using the first trench portion 162 and the second trench portion 164 larger than the first trench portion 162, the metal layer 102a may be formed such that an upper surface of the metal layer 102a positioned in the second trench portion 164 is positioned lower than an upper surface of the metal layer 102a positioned in the first trench portion 162 due, e.g., to the difference in volume between the first trench portion 162 and the second trench portion 164.

For example, electroplating may be performed such that the metal layer 102a is bottom-up filled in the first trench portion 162. Then, the metal layer 102a may be entirely filled in the first trench portion 162, while the metal layer 102a in the second trench portion 164 may be a conformal electroplating layer because a filling speed in the second trench portion 164 is relatively. As a result, a recess portion S may be disposed at an upper surface of the metal layer 102a disposed in the second trench portion 164. That is, the upper surface of the metal layer 102a may be disposed lower than the bonding surface 10s by the recess portion S and may be spaced apart from the bonding surface 10s.

In this case, in the forming of the metal layer 102a, a speed, an aspect, a shape, and/or the like of a formation of the metal layer 102a may be adjusted using additives or the like to effectively control a position of the upper surface of the metal layer 102a in the first and second trench portions 162 and 164. For example, when the electroplating is performed to form the metal layer 102a, bottom-up filling may be effectively induced by using an accelerator that activates electroplating as an additive.

Subsequently, as shown in FIG. 3C, the metal layer 102a (refer to FIG. 3B) disposed on the first insulation layer 160 may be removed by performing a chemical mechanical polishing process on the metal layer 102a. Then, the metal layer 102a disposed inside the first trench portion 162 forms the first bonding pad 122, and the metal layer 102a disposed inside the second trench portion 164 forms the first pattern portion 132. Accordingly, the first chip 100 may be manufactured. Such a first chip 100 may form a chip for hybrid bonding that is bonded to another chip (e.g., second chip 200) by hybrid bonding.

In this case, a portion of the metal layer 102a disposed on a side surface adjacent to an upper surface of the first pattern portion 132 in the second trench portion 164 may be removed. Then, the upper surface of the first pattern portion 132 may be spaced apart from the bonding surface 10s as a whole. This is because the size of the second trench portion 164 is larger than the size of the first trench portion 162 and thus the metal layer 102a in the second trench portion 164 may be polished more than the metal layer 102a in the first trench portion 162 in a chemical mechanical polishing process. In the drawing, it is illustrated that an entire portion of the upper surface of the first pattern portion 132 is disposed on the same plane, but the embodiments are not limited thereto. For example, the upper surface of the first pattern portion 132 may be disposed higher in a side portion than in a center portion, and/or other variations are possible. In addition, in FIG. 3C, the upper surface of the first bonding pad 122 is illustrated as disposed on the same plane as the bonding surface 10s, but the embodiments are not limited thereto. For example, the chemical mechanical polishing process, as shown in FIG. 4C, an upper surface of the first bonding pad 122 may be disposed lower than a bonding surface 10s. Even in this case, the upper surface of the first pattern portion 132 may be disposed lower than the upper surface of the first bonding pad 122.

The chemical mechanical polishing process improves surface roughness of the first chip 100 and/or second chip 200 before a process of bonding the first chip 100 and the second chip 200 using hybrid bonding, and is performed to stably connect the bonding pad 22 for signal transmission in a vertical direction.

In the chemical mechanical polishing process, a polishing material that removes the metal layer 102a may be used. For example, a polishing material that may remove the metal layer 102a but does not remove the first insulation layer 160 and/or a polishing material that may remove the metal layer 102a at a higher speed than the first insulation layer 160 may be used. For example, an acid slurry material may be used in a chemical mechanical polishing process. The acidic slurry material is suitable for adjusting a thickness of the metal layer 102a or a height of the upper surface of the metal layer 102a in the first trench portion 162 and the second trench portion 164 as described above because the acid slurry material has a higher removal speed of the metal layer 102a compared to the first insulation layer 160. However, the embodiments are not limited thereto, and the process of the chemical mechanical polishing process may be performed in any of various process conditions. For example, an alkaline slurry material may be used in a chemical mechanical polishing process.

Subsequently, as shown in FIG. 3D, the bonding semiconductor device 10 may be formed by bonding the first chip 100 and the second chip 200.

In further detail, a second semiconductor device portion 240, a second intermediate insulation layer 250, and a second insulation layer 260 including first and second trench portions 262 and 264 may be formed on a second substrate 210, and a second bonding pad 222 and a second pattern portion 232 may be formed. Accordingly, the second chip 200 may be manufactured. Such a second chip 200 may form a chip for hybrid bonding (e.g., to the first chip 100).

Here, since any of various processes may be applied to the forming of the second semiconductor device portion 240, the second intermediate insulation layer 250, and the second insulation layer 260 including the first and second trench portions 262 and 264, detailed descriptions thereof may be omitted. A process of forming the second bonding pad 222 and the second pattern portion 232 is similar to the a process of forming the first bonding pad 122 and the first pattern portion 132 described with reference to FIG. 3A to FIG. 3C, and therefore a description of the process of forming the first bonding pad 122 and the first pattern portion 132 referring to FIG. 3A to FIG. 3C may be applied as it is to the process of forming the second bonding pad 122 and the second pattern portion 232.

In addition, the bonding semiconductor device 10 may be formed by bonding the first chip 100 and the second chip 200. The bonding of the first chip 100 and the second chip 200 may be performed by annealing while applying pressure in a state that the first insulation layer 160 and the second insulation layer 260 face each other, the first bonding pad 122 and the second bonding pad 222 face each other, and the second trench portion 164 where the first pattern portion 132 is disposed and the second trench portion 264 where the second pattern portion 232 is disposed to face each other. Therefore, the first chip 100 and the second chip 200 may be bonded by the hybrid bonding process.

Here, during the annealing process, the first bonding pad 122 and the second bonding pad 222 may be bonded to have a metal connection structure, and the first insulation layer 160 and the second insulation layer 260 may be bonded to have an insulation connection structure. During the annealing process, a shape or a position of the upper surface of the first pattern portion 132 and/or the second pattern portion 232 may change, but the inner space 32s may be disposed between the first pattern portion 132 and the second pattern portion 232. Accordingly, a metal connection structure is not provided between the first pattern portion 132 and the second pattern portion 232, for example, between a first base layer 132a and a second base layer 232a.

According to at least one embodiment, a bonding semiconductor device having the bonding pad 22 and the separation pattern portion 32d, each having a different structure, or the first or second chip 100 or 200 used therein can be manufactured.

Hereinafter, another example of a manufacturing method of a bonding semiconductor device 10 will be described with reference to FIG. 4A to FIG. 4D, together with FIG. 1 and FIG. 2. Hereinafter, detailed descriptions regarding portions identical or substantially similar to the descriptions referring to FIG. 3A to FIG. 3D may be omitted.

FIG. 4A to FIG. 4D illustrate another example of a manufacturing method of a bonding semiconductor device 10 shown in FIG. 1. FIG. 4A to FIG. 4D illustrate portions corresponding to the lines A-A′ and the line B-B′ of FIG. 1.

As shown in FIG. 4A, a first semiconductor device portion 140, a first intermediate insulation layer 150, and a first insulation layer 160 including first and second trench portions 162 and 164 may be formed on a first substrate 110.

Subsequently, as shown in FIG. 4B, a metal layer 102a may be formed on the first insulation layer 160 while filling the first and second trench portions 162 and 164. FIG. 4B illustrates that an upper surface of the metal layer 102a disposed in the first trench portion 162 and an upper surface of the metal layer 102a disposed in the second trench portion 164 are disposed on the same plane, but the embodiments are not limited thereto. For example, similar to the example shown in FIG. 3B, an upper surface of a metal layer 102a disposed in a second trench portion 164 may be disposed lower than an upper surface of the metal layer 102a disposed in a first trench portion 162.

Subsequently, as shown in FIG. 4C, the metal layer 102a (refer to FIG. 4B) disposed on the first insulation layer 160 may be removed by performing a chemical mechanical polishing process on the metal layer 102a. Then, the metal layer 102a disposed inside the first trench portion 162 forms the first bonding pad 122, and the metal layer 102a disposed inside the second trench portion 164 forms the first pattern portion 132. Accordingly, the first chip 100 may be manufactured.

In this case, the upper surface of the first pattern portion 132 disposed on the second trench portion 164 may be disposed lower than the upper surface of the first bonding pad 122 disposed on the first trench portion 162. For example, a first recess portion S1 may be disposed at the first bonding pad 122 disposed in the first trench portion 162, and a second recess portion S2 may be disposed at the first pattern portion 132 disposed in the second trench portion 164. In this case, a depth of the second recess portion S2 may be greater than a depth of the first recess portion S1.

For example, in the chemical mechanical polishing process, the metal layer 102a in the second trench portion 164 having a relatively large size receives a higher pressure per unit area than the metal layer 102a disposed in the first trench portion 162 having a relatively small size. Accordingly, a greater dishing may occur at the metal layer 102a in the second trench portion 164 compared to the metal layer 102a in the first trench portion 162.

In at least one embodiment, an acidic slurry material may be used in a chemical mechanical polishing process. However, the embodiments are not limited thereto. For example, an alkaline slurry material may be used in a chemical mechanical polishing process.

In the drawing, it is illustrated that an entire portion of the upper surface of the first bonding pad 122 is disposed on the same plane and an entire portion of the upper surface of the first pattern portion 132 is disposed on the same plane, but the embodiments are not limited thereto. For example, portions of the upper surface of the first bonding pad 122 may be disposed at different planes and/or portions of the upper surface of first pattern portion 132 may be disposed at different planes. It is illustrated in the drawing that the first recess portion S1 is formed at the upper surface of the first bonding pad 122, but the embodiments are not limited thereto. For example, after the chemical mechanical polishing process, similar to the example shown in FIG. 3C, the upper surface of the first bonding pad 122 may be positioned on the same (and/or substantially similar) plane as the bonding surface 10s.

Subsequently, as shown in FIG. 4D, the bonding semiconductor device 10 may be formed by bonding the first chip 100 and the second chip 200. Metal expansion or extrusion may occur in the bonding process or annealing process due to, e.g., thermal expansion. Then, the first and/or second bonding pads 122 and 222 expand (or extrude) up to the bonding surface 10s while filling the first recess portion S1, and thus the first bonding pad 122 and the second bonding pad 222 may be bonded at the bonding surface 10s. Since the second recess portion S2 has a greater thickness (in the Z-direction) than the first recess portion S1, even though the first pattern portion 132 and the second pattern portion 232 forming the separation pattern portion 32d are expanded (or extruded) in the annealing process, an inner space 32s may remain between the first pattern portion 132 and the second pattern portion 232.

According to at least one embodiment, a bonding semiconductor device having the bonding pad 22 and the separation pattern portion 32d, each having a different structure, or the first or second chip 100 or 200 used therein can be manufactured.

In at least one embodiment, the process described with reference to FIG. 3A to FIG. 3C and the process described with reference to FIG. 4A to FIG. 4C may be combined with each other in order to form the bonding semiconductor device 10. For example, one of the first chip 100 and the second chip 200 may be formed through the process of FIG. 3A to FIG. 3C, and the other may be formed through the process of FIG. 4A to FIG. 4C. In addition, in FIG. 2, FIG. 3D, and FIG. 4D, the first pattern portion 132 provided in the first chip 100 and the second pattern portion 232 provided in the second chip 200 have the recess portions S, S1, or S2 to form the inner space 32s, but the embodiments are not limited thereto.

In a modified embodiment, as shown in FIG. 5, a first pattern portion 132 included in a first chip 100 may include a recess portion, and a second pattern portion 232 included in a second chip 200 may not include a recess portion. Even in this case, an inner space 32s may be provided between the first pattern portion 132 and the second pattern portion 232 by the recess portion of the first pattern portion 132. FIG. 5 illustrates that lower surface of the second pattern portion 232 is positioned on the same plane as a bonding surface 10s, but the upper surface of the second pattern portion 232 may be more protruded than the bonding surface 10s due to annealing in the bonding process. In another modified embodiment, a second pattern portion 232 included in a second chip 200 may include a recess portion, and a first pattern portion 132 included in a first chip 100 may not include a recess portion. Even in this case, an inner space 32s may be provided between the first pattern portion 132 and the second pattern portion 232 by the recess portion of the second pattern portion 232. In this case, upper surface of the first pattern portion 132 may be positioned on the same plane as the bonding surface 10s or may be positioned more protruded than a bonding surface 10s.

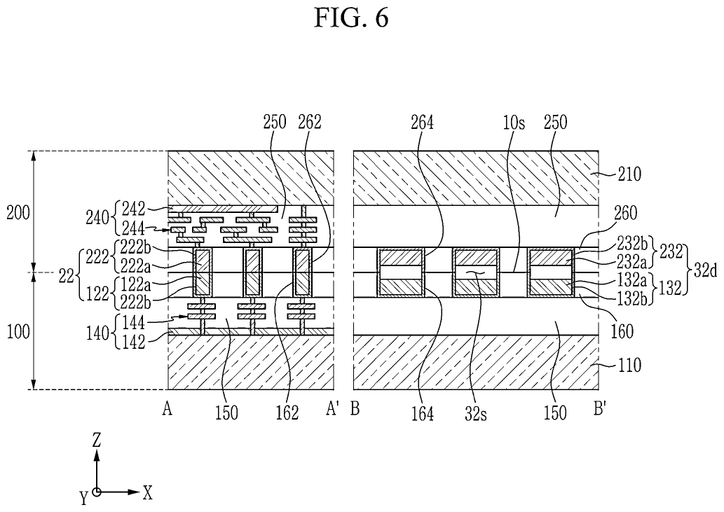

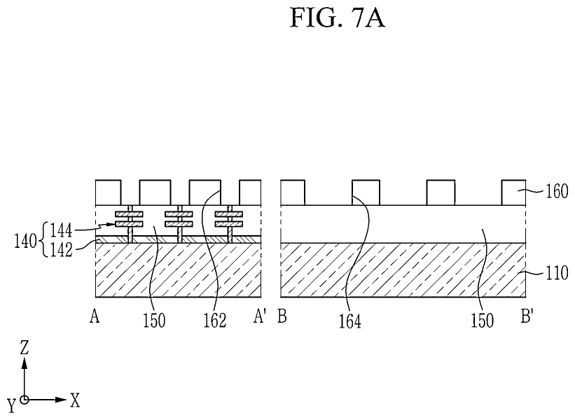

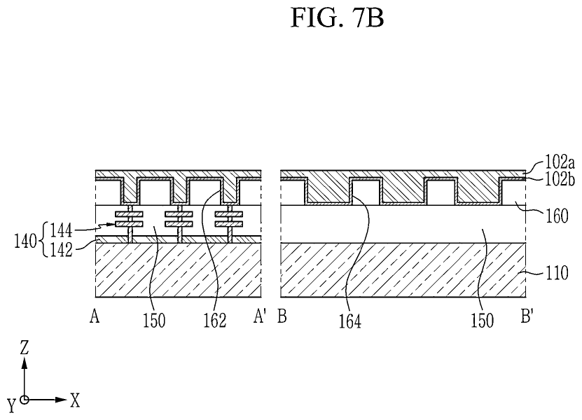

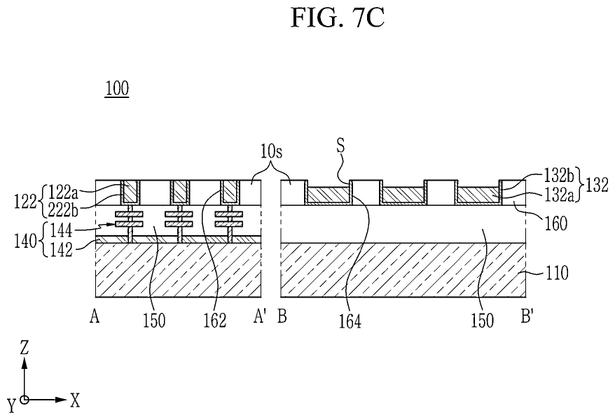

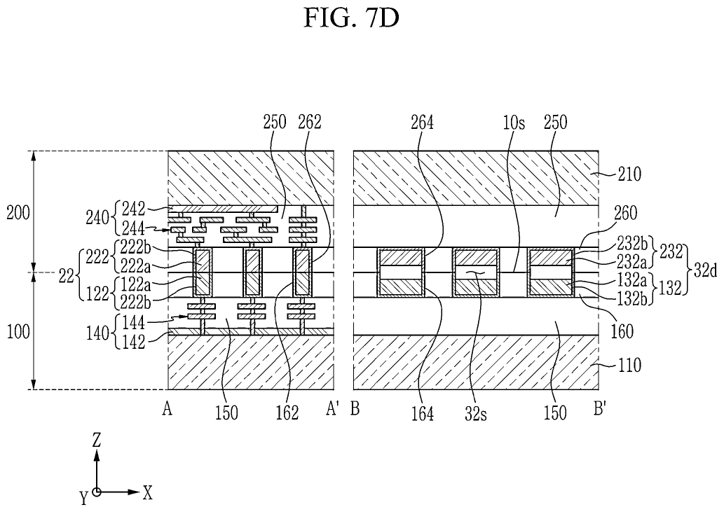

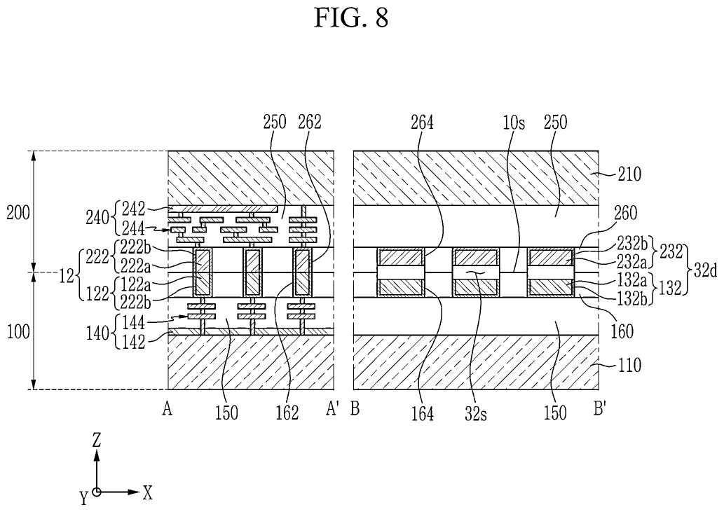

Hereinafter, a bonding semiconductor device and its manufacturing method according to at least one other embodiment will be described in more detail with reference to FIG. 6, FIG. 7A to FIG. 7D, and FIG. 8 to FIG. 10. Detailed descriptions for parts identical or extremely similar to those already described will be omitted.

FIG. 6 is a partial cross-sectional view of a bonding semiconductor device according to at least one embodiment, and FIG. 7A to FIG. 7D illustrate an example of a manufacturing method of the bonding semiconductor device shown in FIG. 6. FIG. 6 and FIG. 7A to FIG. 7D illustrate portions corresponding to the lines A-A′ and B-B′ of FIG. 1.

Referring to FIG. 6, in a bonding semiconductor device according to at least one embodiment, a first pattern portion 132 may include a first base layer 132a and a first barrier layer 132b, and a second pattern portion 232 may include a second base layer 232a and a second barrier layer 232b. The first barrier layer 132b may be formed on a bottom surface and side surfaces of a second trench portion 164, and the first base layer 132a may be disposed on the first barrier layer 132b. Similarly, the second barrier layer 232b may be formed on a bottom surface and side surfaces of the second trench portion 264, and the second base layer 232a may be disposed on the second barrier layer 232b.

A thickness of the first barrier layer 132b may be smaller than a thickness of the first base layer 132a, and a thickness of the second barrier layer 232b may be smaller than a thickness of the second base layer 232a. For example, the thickness of the first barrier layer 132b or the second barrier layer 232b may have a thickness of 10 nm or less. Having such a range may effectively prevent problems caused by expansion or extrusion in an annealing process. However, the embodiments are not limited thereto, and the thickness of the first or second barrier layer 132b or 232b may exceed 10 nm.

In at least one embodiment, the first barrier layer 132b and the second barrier layer 232b may be bonded and connected to each other at a bonding surface 10s, and the first base layer 132a and the second base layer 232a are entirely spaced apart from each other with an inner space 32s interposed therebetween. That is, the first barrier layer 132b and the second barrier layer 232b extend to upper side surfaces of the second trench portions 164 and 264, respectively, and are bonded and connected at the bonding surface 10s, and the first base layer 132a and the second base layer 232a may be respectively disposed away from the bonding surface 10s. Accordingly, the first base layer 132a and the second base layer 232a may form a disconnection structure in which the first base layer 132a and the second base layer 232a are not connected to each other.

That is, in a partition region 30, an insulation connection structure of a first insulation layer 160 and a second insulation layer 260 and a metal connection structure of the first barrier layer 132b and the second barrier layer 232b are provided, but a metal connection structure comprising the first base layer 132a and the second base layer 232a is be provided.

As such, the first barrier layer 132b is formed to entirely separate the second trench portion 164 of the first insulation layer 160 and the first base layer 132a, and the second barrier layer 232b is formed to entirely separate the second trench portion 264 of the second insulation layer 260 from the second base layer 232a, and thus material diffusion between the first and second base layers 132a and 232a and the first insulation layer 160 and the second insulation layer 260 can be effectively prevented and/or mitigated. The first barrier layer 132b may be entirely formed on the bottom surface of the side surfaces of the second trench portion 164 of the first insulation layer 160, and the second barrier layer 232b may be entirely formed on the bottom surface (the upper surface of in FIG. 6) and the side surfaces of the second trench portion 264 of the second insulation layer 260. Since the first and second barrier layers 132b and 232b have relatively thin thicknesses, the bonding of the first and second insulation layers 160 and 260 are not disturbed even when expansion or extrusion occurs during the annealing process. Accordingly, although the first barrier layer 132b and the second barrier layer 232b have a metal connection structure connected to each other, unbonded portions, voids, cracks, or the like is not formed between the first insulation layer 160 and the second insulation layer 260. In addition, the first base layer 132a and the second base layer 232a, which are included with the largest volume in the first pattern portion 132 and second pattern portion 232, respectively, are spaced apart with the inner space 32s interposed therebetween, and an unbonded portion, voids, cracks, or the like can be prevented from being formed between the first and second insulation layers 160 and 260.

For example, a thickness of the inner space 32s (in the Z-direction) may be greater than a thickness of the first barrier layer 132b or the second barrier layer 232b. Accordingly, the thickness of the inner space 32s is secured to a certain thickness or more such that the inner space 32s can be stably provided in each separation pattern portion 32d even when a process error occurs in the manufacturing process. However, the embodiments are not limited thereto, and the thickness of the inner space 32s may be equal to or smaller than the thickness of the first barrier layer 132b or second barrier layer 232b.

In at least one embodiment, the first and/or second bonding pads 122 and 222 may include first and/or second base layers 122a and 222a and first and/or second barrier layers 122b and 222b, respectively. Here, the first and/or second base layers 122a and 222a of the first and/or second bonding pads 122 and 222 may have the same material or stacking structure as the first and/or second base layers 132a and 232a of the first pattern portion 132 and/or second pattern portion 232. In addition, the first and/or second barrier layers 122b and 222b of the first and/or second bonding pads 122 and 222 may have a material or stacking structure as the first and/or second barrier layers 132b and 232b of the first pattern portion 132 and/or second pattern portion 232. For example, in at least one embodiment, the first barrier layer 122b and the first barrier layer 132b may be formed together (e.g., during the same process). However, the embodiments are not limited thereto.

As described above, according to at least one embodiment, the separation pattern portion 32d prevents (or mitigates) unbonded portions, voids, cracks, and/or the like from being formed at a bonding surface, while the first and second barrier layers 132b and 232b prevents (or mitigates) material diffusion. For example, the first and/or second barrier layer 132b and/or 232b, and/or the first and/or second barrier layer 122b and/or 222b may include a barrier metal (for example, tantalum (Ta)) different from the first and/or second base layer 132a and/or 232a, and/or the first and/or second base layer 122a and/or 222a.

An example of a manufacturing method of the bonding semiconductor device shown in FIG. 6 will be described with reference to FIG. 7A to FIG. 7D. FIG. 7A to FIG. 7D illustrate an example of a manufacturing method of the bonding semiconductor device shown in FIG. 6. Hereinafter, detailed descriptions regarding portions identical or substantially similar to the descriptions referring to FIG. 4A to FIG. 4D may be omitted.

As shown in FIG. 7A, a first semiconductor device portion 140, a first intermediate insulation layer 150, and a first insulation layer 160 including first and second trench portions 162 and 164 may be formed on a first substrate 110.

Subsequently, as shown in FIG. 7B, a barrier metal layer 102b and a metal layer 102a may be formed on the first insulation layer 160 while filling the first and second trench portions 162 and 164. In FIG. 7B, it is illustrated that an upper surface of the metal layer 102a disposed in the first trench portion 162 and an upper surface of the metal layer 102a disposed in the second trench portion 164 are disposed on the same plane, however the embodiments are not limited thereto. For example, in another example, similar to the example shown in FIG. 3B, an upper surface of a metal layer 102a disposed in a second trench portion 164 may be disposed lower than an upper surface of the metal layer 102a disposed in a first trench portion 162.

Subsequently, as shown in FIG. 7C, the barrier metal layer 102b (refer to FIG. 7B) and the metal layer 102a (refer to FIG. 7B) disposed on the first insulation layer 160 may be removed by performing a chemical mechanical polishing to the barrier layer 102b and the metal layer 102a. Then, the barrier metal layer 102b and the metal layer 102a disposed inside the first trench portion 162 forms a first barrier layer 122b and a first base layer 122a of a first bonding pad 122, and the barrier metal layer 102b and the metal layer 102a disposed inside the second trench portion 164 form a first barrier layer 132b and a first base layer 132a of a first pattern portion 132. As a result, a first chip 100 may be manufactured.

In this case, a portion of the metal layer 102a disposed inside the second trench portion 164 may be removed such that an upper surface of the first base layer 132a may be entirely spaced apart from a bonding surface 10s. This is because a size of the second trench portion 164 is larger than a size of the first trench portion 162, and the metal layer 102a in the second trench portion 164 may be polished more than the metal layer 102a in the first trench portion 162 in the chemical mechanical polishing process. In the drawing, it is illustrated that an upper surface of the first base layer 132a is disposed on the same plane as a whole, but the embodiments are not limited thereto. For example, the upper surface of the first base layer 132a may be disposed higher in a side portion than in a center portion and other variations are possible.

In this case, the first barrier layer 132b may remain on an upper side of the second trench portion 164 as it is. This may be implemented by using a polishing material in which the metal layer 102a is polished at a higher speed than the first insulation layer 160 and the barrier metal layer 102b in a chemical mechanical polishing process. For example, an acidic slurry material may be used in the chemical mechanical polishing process. However, the embodiments are not limited thereto. In at least one embodiment, a separate process of selectively removing or polishing the metal layer 102a may be further performed after the chemical mechanical polishing process.

As another example, an upper surface of the first barrier layer 132b may be disposed lower than the bonding surface 10s before the bonding process. Even in this case, the upper surface of the first base layer 132a may be disposed lower than the upper surface of the first barrier layer 132b, and in a bonding process or an annealing process, the first barrier layer 132b may be expanded or extruded to extend to the bonding surface 10s. However, other variations are possible.

In addition, in FIG. 7C, it is illustrated that an upper surface of the first bonding pad 122 is disposed on the same plane as the bonding surface 10s, however the embodiments are not limited thereto. For example, after the chemical mechanical polishing process, similar to the example shown in FIG. 4C, the upper surface of the first bonding pad 122 may be disposed lower than the bonding surface 10s. In this case, the upper surface of the first bonding pad 122 may be higher than or at the same plane as the upper surface of the first base layer 132a.

Subsequently, as shown in FIG. 7D, a bonding semiconductor device 10 may be formed by bonding the first chip 100 and the second chip 200.

According to at least one embodiment, a bonding semiconductor device having the bonding pad 22 and the separation pattern portion 32d, each having a different structure, or the first or second chip 100 or 200 used therein can be manufactured by a simple process.

In a modified embodiment, as shown in FIG. 8, a first pattern portion 132 includes a first base layer 132a and a first barrier layer 132b, and a second pattern portion 232 includes a second base layer 232a and a second barrier layer 232b. In this case, the first pattern portion 132 and the second pattern portion 232 may be completely or entirely spaced apart from each other. That is, the first barrier layer 132b and the second barrier layer 232b may be spaced apart from each other, and the first base layer 132a and the second base layer 232a may be spaced apart from each other.

In addition, in FIG. 2 and FIG. 5, the first pattern portion 132 of the first chip 100 is formed of the first base layer 132a and the second pattern portion 232 of the second chip 200 is formed of the second base layer 232a. FIG. 6 and FIG. 8 illustrate that the first pattern portion 132 of the first chip 100 includes the first base layer 132a and the first barrier layer 132b, and the second pattern portion 232 of the second chip 200 includes the second base layer 232a and the second barrier layer 232b. However, the embodiments are not limited thereto. Accordingly, the first pattern portion 132 and the second pattern portion 232 may have different stacking structures. For example, at least one of the first pattern portion 132 and the second pattern portion 232 may include a base layer and a barrier layer, and the other of the first pattern portion 132 and the second pattern portion 232 may include only the base layer.

FIG. 9 is a partial top plan view of a bonding semiconductor device according to at least one embodiments, and FIG. 10 is a partial cross-sectional view of a bonding semiconductor device shown in FIG. 9, taken along lines C-C′ and D-D′. FIG. 9 illustrates a portion corresponding to the enlarged portion of FIG. 1.

Referring to FIG. 9 and FIG. 10, in a bonding semiconductor device according to at least one embodiment, a dummy pattern 36 has a larger size than a bonding pad 22 and may be formed of a separation pattern portion 32d having an inner space 32s. Accordingly, the dummy pattern 36 may serve as a dummy in a partition region 30 and improve reliability of the bonding semiconductor device after a bonding process.

A description of the separation pattern portion 32d forming a key pattern 34 may be applied as it is to the separation pattern portion 32d forming the dummy pattern 36. In FIG. 9, it is illustrated that the separation pattern portion 32d forming the dummy pattern 36 is formed of a first pattern portion 132 including a first base layer 132a and a second pattern portion 232 including a second base layer 232a to have a structure shown in FIG. 2. However, the embodiments are not limited thereto. Therefore, the dummy pattern 36 or the separation pattern portion 32d forming the dummy pattern 36 may have a structure corresponding to any of the embodiments of FIG. 2, FIG. 5, FIG. 6 and FIG. 8 and the modified embodiments thereof.

Although it is not shown in FIG. 10, in at least one embodiment, the key pattern 34 of FIG. 9 may also be formed of the separation pattern portion 32d. However, the embodiments are not limited thereto, and at least one of the key pattern 34 and the dummy pattern 36 may be formed as the separation pattern portion 32d, and other variations are possible.

In the above embodiment, a size of the key pattern 34 and/or the dummy pattern 36 forming the separation pattern portion 32d is larger than a size of the bonding pad 22. Alternatively, the key pattern 34 and/or dummy pattern 36 forming the separation pattern portion 32d may be equal to or smaller than the bonding pad 22 in size. This is because the partition region 30 does not require an electrical bonding and thus an inner space 32s may be provided.

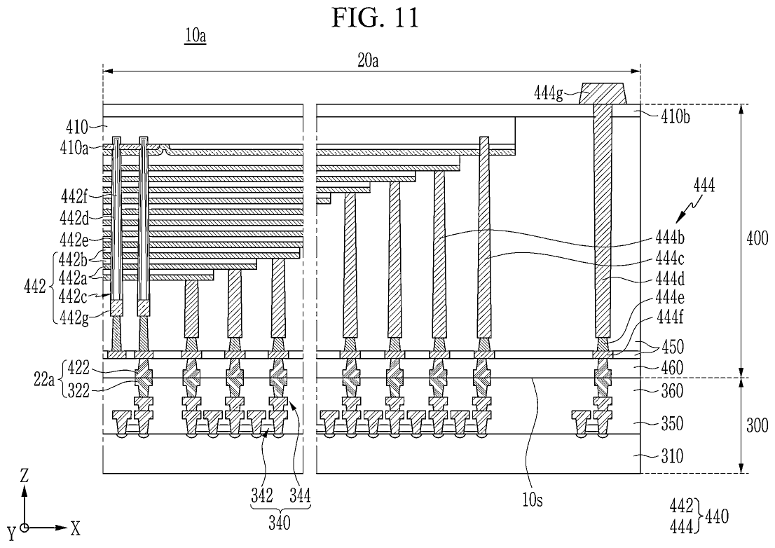

FIG. 11 is a schematic cross-sectional view of an example in which a bonding semiconductor device according to at least one embodiments are formed of a bonding memory device. FIG. 11 illustrates a part of a chip region 20a, and a partition region is not separately illustrated.

Referring to FIG. 11, a bonding memory device 10a according to at least one embodiment may have a chip to chip (C2C) structure bonded by a hybrid bonding method. That is, after manufacturing a first chip 300, which is a lower chip including a circuit region formed on a first substrate 310, and a second chip 400, which is an upper chip including a cell region formed on a second substrate 410, they are bonded to manufacture the bonding memory device 10a.

The bonding memory device 10a according to at least one embodiment may be formed of a vertical bonding NAND flash memory (BV NAND).

The first chip 300 includes a first substrate 310, a first semiconductor device portion 340 including a first semiconductor device layer 342 and a first wiring portion 344, a first intermediate insulation layer 350, and a first insulation layer 360 and a first bonding pad 322 disposed at a bonding surface 10s. The first semiconductor device layer 342 may be connected to the first semiconductor device portion 340 and/or the first substrate 310. Here, for the first substrate 310, the first semiconductor device portion 340 including the first semiconductor device layer 342 and the first wiring portion 344, the first intermediate insulation layer 350, the first insulation layer 360, and the first bonding pad 322, a description of the first substrate 110, the first semiconductor device portion 140 including the first semiconductor device layer 142 and the first wiring portion 144, the first intermediate insulation layer 150, the first insulation layer 160, and the first bonding pad 122, with reference to FIG. 1, FIG. 2, FIG. 3A to FIG. 3D, FIG. 4A to FIG. 4D, FIG. 5, FIG. 6, FIG. 7A to FIG. 7D, and FIG. 8 to FIG. 10, may be applied.

The second chip 400 includes a second substrate 410, a second semiconductor device portion 440 including a second semiconductor device layer 442 and a second wiring portion 444, a second intermediate insulation layer 450, and a second insulation layer 460 and a second bonding pad 422 disposed at a bonding surface 10s. Here, for the second substrate 410, the second semiconductor device portion 440 including the second semiconductor device layer 442 and the second wiring portion 444, the second intermediate insulation layer 450, the second insulation layer 460, and the second bonding pad 422, a description of the second substrate 210, the second semiconductor device portion 240 including the second semiconductor device layer 242 and the second wiring portion 244, the second intermediate insulation layer 250, the second insulation layer 260, and the second bonding pad 222, with reference to FIG. 1, FIG. 2, FIG. 3A to FIG. 3D, FIG. 4A to FIG. 4D, FIG. 5, FIG. 6, FIG. 7A to FIG. 7D, and FIG. 8 to FIG. 10, may be applied.

In at least one embodiment, the second semiconductor device layer 442 may include gate stacking structures 442a and 442b and a channel structure 442c passing through the gate stacking structures 442a and 442b. The gate stacking structures 442a and 442b may include a plurality of gate electrodes 442a and a plurality of insulation layers 442b that are alternately stacked. The channel structure 442c may be disposed vertically with the second substrate 410 by penetrating the gate stacking structures 442a and 442b. The channel structure 442c may include a channel layer 442d and a gate dielectric layer 442e disposed on the channel layer 442d between the gate electrode 442a and the channel layer 442d. The channel structure 442c may further include a core insulation layer 442f disposed inside the channel layer 442d, and may further include a channel pad 442g disposed on the channel layer 442d.

Each channel structure 442c forms one memory cell string, and a plurality of channel structures 442c form rows and columns on a plane, while being spaced apart from each other. For example, when viewed on a cross-section, the channel structure 442c may have an inclined side surface such that its width narrows as it approaches the second substrate 410 according to an aspect ratio. However, the embodiments are not limited thereto, and an arrangement, a structure, a shape, and/or the like of the channel structure 442c may be variously modified.

The channel layer 442d may include a semiconductor material, for example, polysilicon. The core insulation layer 442f may include any of various insulating materials. For example, the core insulation layer 442f may include a silicon oxide, a silicon nitride, a silicon oxynitride, or a combination thereof. The channel pad 442g may be disposed to be electrically connected to the channel layer 442d. The channel pad 442g may include a conductive material, for example, impurity-doped polysilicon. However, the embodiments are not limited to a structure, a material, and/or the like of the channel layer 442d, the core insulation layer 442f, the channel pad 442g, and/or the like.

The gate dielectric layer 442e disposed between the gate electrode 442a and the channel layer 442d may include a tunneling layer, a charge storage layer, and a blocking layer that are sequentially formed on the channel layer 442d. In this case, the tunneling layer is a layer through which charge is tunneled according to a voltage applied to the gate electrode 442a, and may include an insulating material that charge tunneling is possible therethrough. A charge storage layer disposed between the tunneling layer and the blocking layer may be used as a data storage region. The blocking layer may include an insulating material that can prevent an undesirable charge inflow into the gate electrode 442a. A layer forming the gate dielectric layer 442e and a material included therein may be variously modified.

FIG. 11 illustrates that the gate stacking structures 442a and 442b are formed of a single gate stacking structure, but the embodiments may include a plurality of gate stacking structures.

In at least one embodiment, the second wiring portion 444 may include a bit line 444a, a gate contact portion 444b, a source contact portion 444c, an input and output connection wiring 444d, a contact via 444e, a connection wiring 444f, an input and output pad 444g, and/or the like.

Here, the bit line 444a may be electrically connected to the channel structure 442c through the contact via 444e, for example, a bit line contact via. The plurality of gate contact portions 444b may be electrically connected to the plurality of gate electrodes 442a, respectively, and the source contact portion 444c may be electrically connected to a horizontal conductive layer 410a and/or the second substrate 410 forming at least a part of a common source line. The bit line 444a, the gate contact portion 444b, the source contact portion 444c, and/or input and output connection wiring 444d may be electrically connected to the connection wiring 444f. For example, the gate contact portion 444b, the source contact portion 444c and/or the input and output connection wiring 444d may be electrically connected to the connection wiring 444f through the contact via 444e.

The input and output connection wiring 444d may be electrically connected to the input and output pad 444g. The input and output connection wiring 444d may be electrically connected to a part of the second bonding pad 422. The input and output pad 444g, for example, may be disposed on an insulation layer 410b covering an outer surface of the second substrate 410. Depending on the structure of the embodiments, a separate input and output pad electrically connected to the first chip 300 may be provided.

A first insulation layer 360 and a first bonding pad 322 may be disposed at a bonding surface of the first chip 300, and a second insulation layer 460 and a second bonding pad 422 may be disposed at a bonding surface of the second chip 400. At the bonding surface, the first insulation layer 360 and the second insulation layer 460 are bonded, and the first bonding pad 322 and the second bonding pad 422 are bonded to form a bonding pad 22a.

FIG. 11 illustrates that the bonding semiconductor device according to at least one embodiment may be applied to the bonding memory device 10a as an example. However, the embodiments are not limited thereto, and as described above, the bonding semiconductor device may be applied to any of various semiconductor devices, semiconductor element, semiconductor units, or semiconductor packages.

While some examples have been described in connection with what is presently considered to be some practical embodiments, it is to be understood that the disclosure is not limited to the disclosed embodiments, and that that the disclosure is intended to cover various modifications and equivalent arrangements included within the spirit and scope of the appended claims.

What is claimed is:

1. A bonding semiconductor device comprising:
a first chip including a first bonding pad; and
a second chip including a second bonding pad,
wherein the bonding semiconductor device includes a chip region and a partition region,
the chip region includes a bonding pad comprising the first bonding pad of the first chip bonded to the second bonding pad of the second chip, and
the partition region includes a separation pattern portion in which a first base layer of a first pattern portion of the first chip and a second base layer of a second pattern portion of the second chip are entirely separated from each other and define an inner space.

2. The bonding semiconductor device of claim 1, wherein
the first chip includes a first insulation layer,
the second chip includes a second insulation layer bonded to the first insulation layer, and
a bonding surface between the first insulation layer and the second insulation layer and the inner space between the first base layer and the second base layer are between the first chip and the second chip in the partition region.

3. The bonding semiconductor device of claim 1, wherein, in cross-section, a width of the separation pattern portion is greater than a width of the bonding pad.

4. The bonding semiconductor device of claim 1, wherein, in cross-section, a thickness of the inner space is smaller than a sum of a thickness of the first base layer and a thickness of the second base layer.

5. The bonding semiconductor device of claim 1, wherein, in cross-section, a width of the separation pattern portion is greater than a thickness of the inner space.

6. The bonding semiconductor device of claim 1, wherein the first chip further comprises a first insulation layer defining a first trench portion and a second trench,
wherein the first bonding pad is in the first trench, and
the first pattern portion is in the second trench such that the first base layer does not completely cover a side surface of the second trench portion.

7. The bonding semiconductor device of claim 1, wherein the first pattern portion and the second pattern portion form a disconnection structure such that the first pattern portion and the second pattern portion are not connected with each other.

8. The bonding semiconductor device of claim 1, wherein
the first base layer is on a first barrier layer having a thinner thickness than the first base layer,
the second base layer is on a second barrier layer having a thinner thickness than the second base layer, and
the first barrier layer and the second barrier layer are directly connected to each other at a bonding surface between the first chip and the second chip.

9. The bonding semiconductor device of claim 8, wherein a thickness of the inner space is larger than a thickness of at least one of the first barrier layer or second barrier layer.

10. The bonding semiconductor device of claim 1, wherein the separation pattern portion is included in at least one of a key pattern or a dummy pattern.

11. The bonding semiconductor device of claim 1, wherein the bonding semiconductor device comprises a vertical bonding NAND flash memory.

12. A chip for a bonding semiconductor device including a chip region and an external region, the chip comprising:
a substrate;
an insulation layer on the substrate and defining a first trench portion and a second trench portion, the first trench portion in the chip region and having a first size and the second trench portion in the external region and having a second size larger than the first size;
a bonding pad in the first trench portion; and
a pattern portion in the second trench portion, the pattern porting including a base layer,
wherein an uppermost surface of the base layer is lower than an upper surface of the insulation layer.

13. The chip for the bonding semiconductor device of claim 12, wherein the uppermost surface of the base layer is lower than an upper surface of the bonding pad.

14. The chip for the bonding semiconductor device of claim 12, wherein an upper surface of the bonding pad is lower than or at a same plane as the upper surface of the insulation layer.

15. The chip for the bonding semiconductor device of claim 12, wherein the pattern portion does not contact an upper side surface of the second trench portion such that the pattern portion is spaced apart from the upper surface of the insulation layer.

16. The chip for the bonding semiconductor device of claim 12, wherein
the pattern portion includes a barrier layer between the base layer and the insulation layer, the barrier layer having a thickness thinner than that of the base layer, and
the barrier layer is on a bottom surface and side surfaces of the second trench portion and extends up to the upper surface of the insulation layer.

17. A manufacturing method for a chip for a bonding semiconductor device including a chip region and an external region, the method comprising:
forming an insulation layer on a substrate such that the insulation layer includes a first trench portion and a second trench portion, the first trench portion in the chip region and having a first size and the second trench portion in the external region and having a second size larger than the first size;
forming a metal layer on the insulation layer such that the metal layer fills at least a part of the first trench portion and the second trench portion; and
removing a portion of the metal layer such that a bonding pad is formed inside the first trench portion and a pattern portion, including a base layer, is formed inside the second trench portion and an uppermost surface of the base layer is lower than an upper surface of the insulation layer.

18. The manufacturing method of the chip for the bonding semiconductor device of claim 17, wherein the forming of the metal layer includes
forming the metal layer such that an upper surface of a portion the metal layer in the second trench portion is lower than an upper surface of a portion the metal layer in the first trench portion.

19. The manufacturing method of the chip for the bonding semiconductor device of claim 17, wherein the removing of the metal layer includes
removing the metal layer by a chemical mechanical polishing process using an acidic slurry material such that an upper surface of the metal layer in the second trench portion is lower than an upper surface of the metal layer in the first trench portion.

20. The manufacturing method of the chip for the bonding semiconductor device of claim 17, wherein
the chip for the bonding semiconductor device is configured to be hybrid bonded to another chip including a corresponding bonding pad.
